(19) United States
(12) Patent Application Publication
(10) Pub. No.: US 2025/0145836 A1
(43) Pub. Date: May 8, 2025

(54) WATER-REPELLING AGENT FOR ELECTROCONDUCTIVE ARTICLE SURFACE, WATER-REPELLENCY-IMPARTING METHOD FOR ELECTROCONDUCTIVE ARTICLE SURFACE, METHOD FOR SELECTIVELY IMPARTING WATER REPELLENCY FOR REGION HAVING ELECTROCONDUCTIVE ARTICLE SURFACE, SURFACE TREATMENT METHOD, AND METHOD FOR FORMING FILM ON SELECTED REGION OF SUBSTRATE SURFACE

(71) Applicant: TOKYO OHKA KOGYO CO., LTD., Kawasaki-shi (JP)

(72) Inventors: Daichi TANAKA, Kawasaki-shi (JP); Kenji SEKI, Kawasaki-shi (JP); Kazuya TAJIMA, Kawasaki-shi (JP)

(21) Appl. No.: 18/730,248

(22) PCT Filed: Jan. 5, 2023
(86) PCT No.: PCT/JP2023/000097

§ 371 Date: Jul. 18, 2024

(30) Foreign Application Priority Data
Jan. 24, 2022 (JP) 2022-008926

(51) Int. Cl. C09D 5/16; C09D 7/63; C23C 16/02; C23C 16/455

(52) U.S. Cl. CPC C09D 5/1625; C09D 7/63; C23C 16/02; C23C 16/45525

(57) ABSTRACT

A water-repelling agent for an electroconductive article surface, including a compound that contains an aromatic ring, an adsorption group which is bonded to the aromatic ring and is an amino group, a phosphonic acid group, an acid anhydride group, a thiol group, or an acid chloride group, and a linear or branched alkyl group or a linear or branched fluorinated alkyl group bonded to the aromatic ring

### TECHNICAL FIELD

The present invention relates to a water-repelling agent for an electroconductive article surface, a water repellency-imparting method for an electroconductive article surface, a method for selectively imparting water repellency to a region having an electroconductive article surface, a surface treatment method, and a method for forming a film on a selected region of a substrate surface.

Priority is claimed on Japanese Patent Application No. 2022-008926, filed Jan. 24, 2022, the content of which is incorporated herein by reference.

### BACKGROUND ART

In recent years, with the progress of high integration and miniaturization of semielectroconductive article devices, miniaturization of organic patterns used as masks and inorganic patterns prepared by etching treatments has proceeded, and thus the film thickness needs to be controlled at an atomic layer level.

As a method for forming a film, which is thin at an atomic layer level, on a substrate, an atomic layer deposition method (ALD; hereinafter, also simply referred to as “ALD method”) is known. The ALD method is known to have both high step coverage and film thickness controllability as compared with a typical chemical vapor deposition (CVD) method.

The ALD method is a thin-film forming technique of alternately supplying two kinds of gases having elements constituting a film intended to be formed as main components onto a substrate and repeatedly forming a thin film a plurality of times on the substrate in an atomic layer unit to form a film having a desired thickness.

In the ALD method, a self-control function (self-limit function) of growth in which only one layer or several layers of raw material gas components are adsorbed on a substrate surface while the raw material gases are supplied and the extra raw material gases do not contribute to the growth is used.

For example, in a case where an Al₂O₃ film is formed on a substrate, a raw material gas consisting of trimethyl aluminum (TMA) and an oxidizing gas are used. Further, in a case where a nitride film is formed on a substrate, a nitride gas is used in place of the oxidizing gas.

In recent years, a method for forming a film on a selected region of a substrate surface using an ALD method has been attempted. Along with such attempts, there has been a demand for a substrate having a region-selectively modified substrate surface so that the substrate can be suitably applied to a method for forming a film on a selected region of a substrate according to the ALD method. In a method for forming a film, control of the film thickness at an atomic layer level, step coverage, and miniaturization of patterning are expected by using the ALD method.

For example, Non-Patent Document 1 describes that film formation using an ALD method is region-selectively inhibited by forming a self-assembled monolayer (SAM) of octadecylphosphonic acid.

### CITATION LIST

### Non-Patent Document

### Non-Patent Document 1

Dara Bobb-Semple, Katie Lynn Nardi, Nerissa Draeger, Dennis M. Hausmann, and Stacey F. Bent. Area-Selective Atomic Layer Deposition Assisted by Self-Assembled Monolayers: A Comparison of Cu, Co, W, and Ru. Chem. Mater. 2019, 31, pp. 1635 to 1645.

### SUMMARY OF INVENTION

### Technical Problem

In the method for forming a film on a selected region of a substrate surface using an ALD method, typically, film formation on the substrate surface to which water repellency has been imparted is inhibited by selectively imparting water repellency to a region of the substrate surface. For example, in a case where a film is formed on a selected insulator surface on the substrate surface where the electroconductive article surface and the insulator surface are mixed, it is necessary to impart water repellency to the selected electroconductive article surface.

The present invention has been made in consideration of the above-described circumstances, and an object thereof is to provide a water-repelling agent for an electroconductive article surface capable of satisfactorily imparting water repellency to the electroconductive article surface, a water repellency-imparting method for an electroconductive article surface using the water-repelling agent for an electroconductive article surface, a method for selectively imparting water repellency to a region having an electroconductive article surface, a surface treatment method, and a method for forming a film on a selected region of a substrate surface.

### Solution to Problem

In order to achieve the above-described object, the present invention employs the following configurations.

According to a first aspect of the present invention, there is provided a water-repelling agent for an electroconductive article surface, including: a compound (P1) that contains an aromatic ring, an adsorption group which is bonded to the aromatic ring and selected from the group consisting of an amino group, a phosphonic acid group, an acid anhydride group, a thiol group, and an acid chloride group, and a linear or branched alkyl group or a linear or branched fluorinated alkyl group bonded to the aromatic ring.

According to a second aspect of the present invention, there is provided a water repellency-imparting method for an electroconductive article surface, the method including: exposing the electroconductive article surface to the water-repelling agent for an electroconductive article surface according to the first aspect.

According to a third aspect of the present invention, there is provided a method for selectively imparting water repellency to a region having an electroconductive article surface in a substrate having a surface including two or more regions formed of materials different from each other, in which at least one of the two or more regions is the electroconductive article surface, the method including: exposing the substrate surface to the water-repelling agent for an electroconductive article surface according to the first aspect.

According to a fourth aspect of the present invention, there is provided a surface treatment method for a substrate having a surface including two or more regions formed of materials different from each other, in which at least one of the two or more regions is an electroconductive article surface, the method including: exposing the surface to the water-repelling agent for an electroconductive article surface according to the first aspect.

According to a fifth aspect of the present invention, there is provided a method for forming a film on a selected region of a substrate surface, the method including: performing a surface treatment on the substrate surface by the surface treatment method according to the fourth aspect; and forming a film on the substrate surface subjected to the surface treatment by an atomic layer deposition method, in which an accumulation amount of a film-forming material from the atomic layer deposition method region-selectively varies.

### Advantageous Effects of Invention

According to the present invention, it is possible to provide a water-repelling agent for an electroconductive article surface capable of satisfactorily imparting water repellency to the electroconductive article surface, a water repellency-imparting method for an electroconductive article surface using the water-repelling agent for an electroconductive article surface, a method for selectively imparting water repellency to a region having an electroconductive article surface, a surface treatment method, and a method for forming a film on a selected region of a substrate surface.

### DESCRIPTION OF EMBODIMENTS

In the present specification and the scope of the present claims, the term “aliphatic” is a relative concept used in relation to the term “aromatic”, and defines a group or compound that has no aromaticity.

The term “alkyl group” includes a linear, branched, or cyclic monovalent saturated hydrocarbon group unless otherwise specified. The same applies to the alkyl group in an alkoxy group.

The term “alkylene group” includes a linear, branched, or cyclic divalent saturated hydrocarbon group unless otherwise specified.

Examples of “halogen atom” include a fluorine atom, a chlorine atom, a bromine atom, and an iodine atom.

In the present specification and the scope of the present patent claims, asymmetric carbons and enantiomers or diastereomers may be present depending on the structures of the chemical formulae. In this case, these isomers are represented by one chemical formula. These isomers may be used alone or in the form of a mixture.

### <First Aspect: Water-Repelling Agent for Electroconductive Article Surface>

A first aspect of the present invention relates to a water-repelling agent for an electroconductive article surface. The water-repelling agent for an electroconductive article surface according to the present aspect contains a compound (P1) containing an aromatic ring, an adsorption group that is bonded to the aromatic ring and selected from the group consisting of an amino group, a phosphonic acid group, an acid anhydride group, a thiol group, and an acid chloride group, and a linear or branched alkyl group or a linear or branched fluorinated alkyl group bonded to the aromatic ring.

### (Compound (P1))

The compound (P1) is a compound containing an aromatic ring, an adsorption group that is bonded to the aromatic ring and selected from the group consisting of an amino group, a phosphonic acid group, an acid anhydride group, a thiol group, and an acid chloride group, and a linear or branched alkyl group or a linear or branched fluorinated alkyl group bonded to the aromatic ring.

The aromatic ring of the compound (P1) is not particularly limited as long as the aromatic ring is a cyclic conjugated system having (4n+2) π electrons, and may be a polycyclic group or a monocyclic group. The aromatic ring may be an aromatic hydrocarbon ring or an aromatic heterocyclic ring. Examples of the heteroatom of the aromatic heterocyclic ring include an oxygen atom, a sulfur atom, and a nitrogen atom. Specific examples of the aromatic heterocyclic ring include a pyridine ring and a thiophene ring.

The aromatic ring is preferably an aromatic hydrocarbon ring and more preferably an aromatic ring having one or two benzene rings. Specific examples of the aromatic ring include a benzene ring, a naphthalene ring, and a biphenyl ring.

The aromatic ring is bonded to an adsorption group selected from the group consisting of an amino group, a phosphonic acid group, an acid anhydride group, a thiol group, and an acid chloride group, and a linear or branched alkyl group or a linear or branched fluorinated alkyl group. The adsorption group is directly bonded to a carbon atom constituting the aromatic ring. The alkyl group or the fluorinated alkyl group is directly bonded to a carbon atom constituting the aromatic ring.

The term “adsorption group” denotes a functional group having adsorptivity to the electroconductive article surface. In a case where the electroconductive article surface is treated with the compound (P1), the compound (P1) is adsorbed on the electroconductive article surface due to the adsorption group to form a SAM. In the compound (P1), the adsorption group is selected from the group consisting of an amino group, a phosphonic acid group, an acid anhydride group, a thiol group, and an acid chloride group. Examples of the acid anhydride group include a succinic anhydride group. As the adsorption group, an amino group, a thiol group, a phosphonic acid group, or an acid anhydride group is preferable, an amino group, a thiol group, or a phosphonic acid group is more preferable, an amino group or a thiol group is still more preferable, and an amino group is particularly preferable.

The number of the adsorption groups bonded to the aromatic ring may be one or two or more. In a case where the aromatic ring is a benzene ring, the number of the adsorption groups may be 1 to 5, 1 to 4, 1 to 3, 1, or 2. In a case where the aromatic ring is a naphthalene ring, the number of the adsorption groups may be 1 to 7, 1 to 6, 1 to 5, 1 to 4, 1 to 3, 1, or 2. In a case where the aromatic ring is a biphenyl ring, the number of the adsorption groups may be 1 to 9, 1 to 8, 1 to 7, 1 to 6, 1 to 5, 1 to 4, 1 to 3, 1, or 2. The number of the adsorption groups is preferably in a range of 1 to 4, more preferably in a range of 1 to 3, still more preferably 1 or 2, and particularly preferably 1.

In a case where a plurality of adsorption groups are bonded to the aromatic ring, the plurality of adsorption groups may be the same as or different from each other.

The linear or branched alkyl group or the linear or branched fluorinated alkyl group bonded to the aromatic ring has preferably 1 to 45 carbon atoms, more preferably 1 to 40 carbon atoms, and still more preferably 1 to 35 carbon atoms. In a case where the alkyl group or the alkyl group of the fluorinated alkyl group is branched, the number of carbon atoms thereof is preferably in a range of 3 to 45, more preferably in a range of 3 to 40, and still more preferably in a range of 3 to 35. The number of carbon atoms in the alkyl group or the fluorinated alkyl group is not particularly limited, but may be 2 or more. 3 or more, 4 or more, 5 or more, 6 or more, 7 or more, 8 or more, 9 or more, 10 or more, 12 or more, 14 or more, or 16 or more and may be 45 or less, 40 or less, 35 or less, 30 or less, 28 or less, 26 or less, 24 or less, 22 or less, or 20 or less. The number of carbon atoms in the alkyl group or the fluorinated alkyl group may be in a range of 5 to 45, 5 to 40, 5 to 35, 8 to 35, or 8 to 30. In a case where the adsorption group is a phosphonic acid group, the number of carbon atoms in the alkyl group or the fluorinated alkyl group may be 5 or more and is preferably in a range of 5 to 45, more preferably in a range of 5 to 40, and still more preferably in a range of 5 to 35.

Specific examples of the linear or branched alkyl group include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, a docosyl group, and isomers of the above-described alkyl groups.

The linear or branched fluorinated alkyl group is a group in which at least some hydrogen atoms of a linear or branched alkyl group have been substituted with fluorine atoms. Examples of the linear or branched fluorinated alkyl group include a group in which at least some hydrogen atoms of the above-described linear or branched alkyl group have been substituted with fluorine atoms. The proportion of the hydrogen atoms substituted with fluorine atoms in the linear or branched fluorinated alkyl group is not particularly limited. The fluorinated alkyl group may be a perfluoroalkyl group.

The number of linear or branched alkyl groups or linear or branched fluorinated alkyl groups bonded to the aromatic ring may be 1 or 2 or more. In a case where the aromatic ring is a benzene ring, the number of the alkyl groups or fluorinated alkyl groups may be 1 to 5, 1 to 4, 1 to 3, 1, or 2. In a case where the aromatic ring is a naphthalene ring, the number of the alkyl groups or fluorinated alkyl groups may be 1 to 7, 1 to 6, 1 to 5, 1 to 4, 1 to 3, 1, or 2. In a case where the aromatic ring is a biphenyl ring, the number of the alkyl groups or fluorinated alkyl groups may be 1 to 9, 1 to 8, 1 to 7, 1 to 6, 1 to 5, 1 to 4, 1 to 3, 1, or 2. The number of the alkyl groups or fluorinated alkyl groups is preferably in a range of 1 to 4, more preferably in a range of 1 to 3, still more preferably 1 or 2, and particularly preferably 1.

In a case where a plurality of alkyl groups or fluorinated alkyl groups are bonded to the aromatic ring, the plurality of alkyl groups or fluorinated alkyl groups may be the same as or different from each other.

From the viewpoint of avoiding interference with the adsorption group, it is preferable that the alkyl group or the fluorinated alkyl group is not bonded to the ortho position of the adsorption group in the aromatic ring.

The compound (P1) may contain other groups in addition to the adsorption group and the alkyl group or fluorinated alkyl group described above. Examples of the other groups include an organic group (excluding the linear or branched alkyl group and the linear or branched fluorinated alkyl group). Examples of the organic group include a hydrocarbon group which may have a substituent. The above-described hydrocarbon group may be an aliphatic hydrocarbon group or an aromatic hydrocarbon group. The number of carbon atoms in the hydrocarbon group may be 1 to 12, 1 to 10, 1 to 8, 1 to 6, 1 to 4, 1 to 3, 1, or 2.

The aliphatic hydrocarbon group may be saturated or unsaturated. The aliphatic hydrocarbon group may be linear or branched, and may have a cyclic structure. The cyclic structure may be monocyclic or polycyclic. The cyclic structure may have an aliphatic hydrocarbon ring or an aliphatic heterocyclic ring.

The aromatic hydrocarbon group may be monocyclic or polycyclic. The aromatic hydrocarbon group may have an aromatic hydrocarbon ring or an aromatic heterocyclic ring.

Examples of the substituent that the hydrocarbon group may have include a functional group other than the above-described adsorption group. Specific examples of the substituent include a hydroxy group, a carboxy group, a halogen atom, and an alkoxy group, but the substituent is not limited thereto.

Examples of the compound (P1) include a compound represented by General Formula (P1-1).

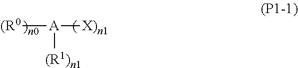

[In the formula, R⁰ represents a linear or branched alkyl group or a linear or branched fluorinated alkyl group, R′ represents an organic group (here, excluding a group corresponding to R⁰), A represents a group in which (n0+n1+nx) hydrogen atoms are removed from a benzene ring, a group in which (n0+n1+nx) hydrogen atoms are removed from a naphthalene ring, or a group in which (n0+n1+nx) hydrogen atoms are removed from a biphenyl ring, X represents an adsorption group selected from the group consisting of an amino group, a phosphonic acid group, an acid anhydride group, a thiol group, and an acid chloride group, n0 and nx each independently represent an integer of 1 or greater, and n1 represents an integer of 0 or greater. Here, n0+n1+nx≤6 is satisfied in a case where A represents the group in which (n0+n1+nx) hydrogen atoms are removed from a benzene ring, n0+n1+nx≤8 is satisfied in a case where A represents the group in which (n0+n1+nx) hydrogen atoms are removed from a naphthalene ring, and n0+n1+nx≤10 is satisfied in a case where A represents the group in which (n0+n1+nx) hydrogen atoms are removed from a biphenyl ring. A plurality of R⁰'s may be the same as or different from each other in a case where no represents 2 or greater, a plurality of R¹'s may be the same as or different from each other in a case where n1 represents 2 or greater, and a plurality of X's may be the same as or different from each other in a case where nx represents 2 or greater.]

In Formula (P1-1), A represents a group in which (n0+n1+nx) hydrogen atoms are removed from a benzene ring, a group in which (n0+n1+nx) hydrogen atoms are removed from a naphthalene ring, or a group in which (n0+n1+nx) hydrogen atoms are removed from a biphenyl ring.

In Formula (P1-1), R⁰ represents a linear or branched alkyl group or a linear or branched fluorinated alkyl group.

Examples of the linear or branched alkyl group or the linear or branched fluorinated alkyl group as R⁰ include the same groups as those for the linear or branched alkyl group or the linear or branched fluorinated alkyl group described above.

R⁰ represents preferably a linear alkyl group or a linear fluorinated alkyl group and more preferably a linear alkyl group having 1 to 30 carbon atoms or a linear fluorinated alkyl group having 1 to 30 carbon atoms. Specific examples of R⁰ include an n-octadecyl group.

In Formula (P1-1), X represents an adsorption group selected from the group consisting of an amino group, a phosphonic acid group, an acid anhydride group, a thiol group, and an acid chloride group. Examples of the acid anhydride group include a succinic anhydride group.

In Formula (P1-1), R¹ represents an organic group (here, excluding a group corresponding to R⁰).

Examples of the organic group as R¹ include the same groups as those for the organic group described above.

In Formula (P1-1), n0 and nx each independently represent an integer of 1 or greater. n0 and nx represent preferably 1 to 4, more preferably 1 to 3, and still more preferably 1 or 2.

In Formula (P1-1), n1 represents an integer of 0 or greater. n1 represents preferably 0 to 4, more preferably 0 to 3, still more preferably 0 to 2, and particularly preferably 0 or 1.

In a case where no represents 2 or greater, a plurality of R⁰'s may be the same as or different from each other. In a case where nx represents 2 or greater, a plurality of X's may be the same as or different from each other. In a case where n1 represents 2 or greater, a plurality of R¹'s may be the same as or different from each other.

A compound represented by General Formula (P1-1-1) is preferable as the compound (P1).

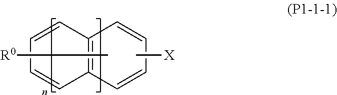

[In the formula, R⁰ represents a linear or branched alkyl group or a linear or branched fluorinated alkyl group, X represents an adsorption group selected from the group consisting of an amino group, a phosphonic acid group, an acid anhydride group, a thiol group, and an acid chloride group, and n represents 0 or 1.]

In Formula (P1-1-1), R⁰ and X each have the same definition as that for R⁰ and X in Formula (P1-1).

In Formula (P1-1-1), n represents 0 or 1. It is preferable that n represents 0.

Preferred examples of the compound (P1) are shown below. In the formula, R⁰ and X each have the same definition as that for R⁰ and X in Formula (P1-1).

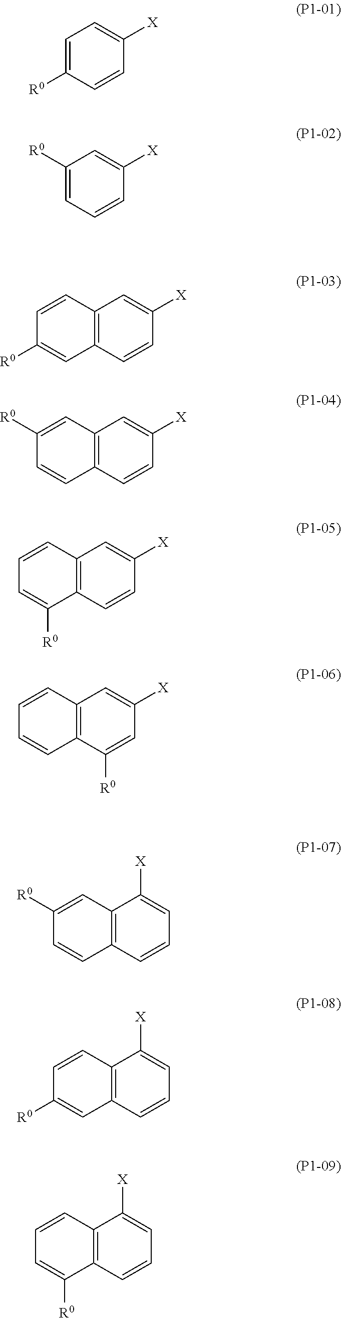

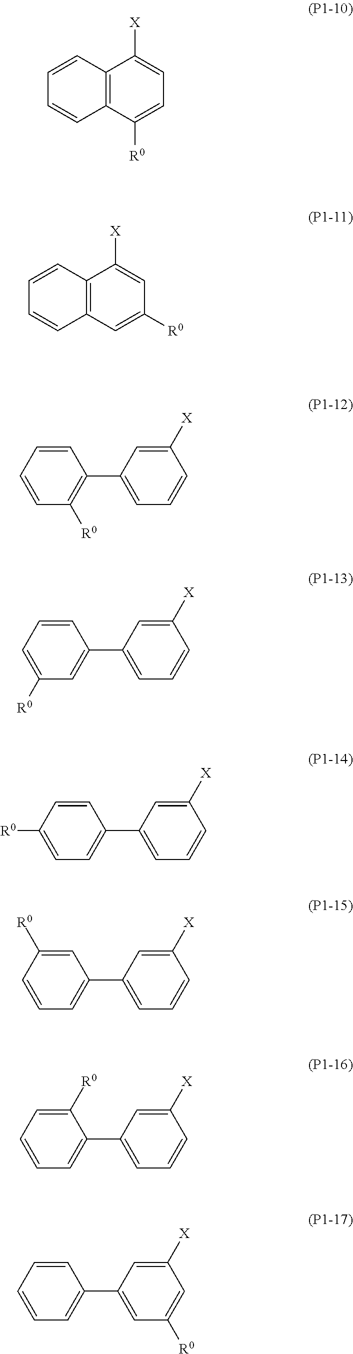

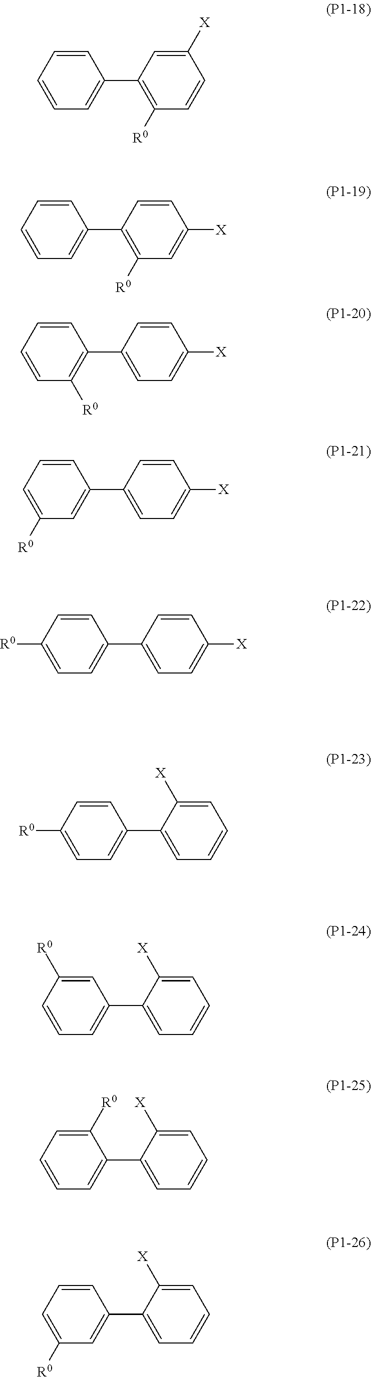

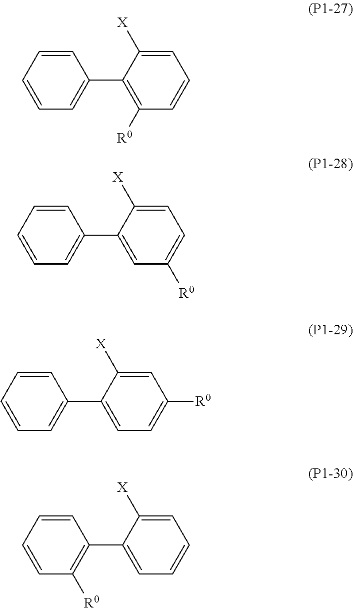

Specific examples of the compound (P1) include 4-n-octadecylaniline, 4-n-pentylaniline, 4-n-hexylaniline, 4-n-heptylaniline, 4-n-octylaniline, 4-n-nonylaniline, 4-n-decylaniline, 4-n-dodecylaniline, 4-n-tetradecylaniline, 4-n-pentadecylaniline, 4-n-hexadecylaniline, 4-methylbenzenethiol, 4-n-propylbenzenethiol, 4-n-butylbenzenethiol, 4-n-pentylbenzenethiol, and 4-n-dodecylbenzenethiol. Among these, 4-n-octadecylaniline or 4-methylbenzenethiol is preferable.

The compound (P1) may be used alone or in combination of two or more kinds thereof.

The amount of the compound (P1) in the water-repelling agent for an electroconductive article surface is preferably in a range of 0.0001% to 5% by mass, more preferably in a range of 0.001% to 4% by mass, still more preferably in a range of 0.005% to 3% by mass, and even still more preferably in a range of 0.008% to 3% by mass with respect to the total mass of the water-repelling agent for an electroconductive article surface.

In a case where the amount of the compound (P1) is in the above-described preferable ranges, the compound (P1) is likely to be adsorbed on the electroconductive article surface, and the water repellency of the electroconductive article surface is improved.

The water-repelling agent for an electroconductive article surface according to the present embodiment may be free of octadecylphosphonic acid, phenylphosphonic acid, and benzenethiol. The water-repelling agent for an electroconductive article surface according to the present embodiment may contain no SAM forming material other than the compound (P1).

### (Optional Component)

The water-repelling agent for an electroconductive article surface according to the present embodiment may contain optional components in addition to the compound (P1). Examples of the optional component include an organic solvent and water.

### <<Organic Solvent(S)>>

It is preferable that the water-repelling agent for an electroconductive article surface according to the present embodiment contains an organic solvent (hereinafter, also referred to as “organic solvent (S)”).

The organic solvent is not particularly limited, but an organic solvent having a relative permittivity of 35 or less is preferable. Examples of the organic solvent include methanol (relative permittivity: 33), diethylene glycol monobutyl ether (BDG) (relative permittivity: 13.70), propylene glycol monomethyl ether (PE) (relative permittivity: 12.71), benzyl alcohol (relative permittivity: 13), 2-heptanone (relative permittivity: 11.74), butyl glycol acetate (relative permittivity: 8.66), tert-butyl alcohol (relative permittivity: 12.5), 1-octanol (relative permittivity: 10.21), isobutanol (relative permittivity: 18.22), benzotrifluoride (relative permittivity: 9.18), decahydronaphthalene (relative permittivity: 2.16), cyclohexane (relative permittivity: 1.99), decane (relative permittivity: 1.99), isobutyl alcohol (relative permittivity: 18.22), ethyl lactate (EL) (relative permittivity: 13.22), diethylene glycol monomethyl ether (relative permittivity: 15.76), 1-nonanol (relative permittivity: 9.13), toluene (relative permittivity: 2.37), propylene glycol monomethyl ether acetate (PM) (relative permittivity: 9.4), methyl isobutyl carbinol (MIBC) (relative permittivity: 10.47). 2,6-dimethyl-4-heptanol (relative permittivity: 2.98), 2-ethyl-1-butanol (relative permittivity: 12.6), 2-butanone oxime (relative permittivity: 2.9), n-dibutyl ether (relative permittivity: 3.33), butyl butyrate (relative permittivity: 4.55), and 2,6-dimethyl-4-heptanone (relative permittivity: 9.82).

Among these, as the organic solvent (S), methanol (relative permittivity: 33), diethylene glycol monobutyl ether (BDG) (relative permittivity: 13.70), polyethylene glycol (PE) (relative permittivity: 12.71), benzyl alcohol (relative permittivity: 12.70). 2-heptanone (relative permittivity: 11.74), butyl glycol acetate (relative permittivity: 8.66), tert-butyl alcohol (relative permittivity: 12.5), 1-octanol (relative permittivity: 10.21), isobutanol (relative permittivity: 18.22), or 4-methyl-2-pentanol (relative permittivity: 10.47) is preferable.

The relative permittivity of the organic solvent is preferably 30 or less, 25 or less, 20 or less, 15 or less, 13 or less, 12 or less, 11 or less, 10 or less, 9 or less, 8 or less, 7 or less, 6 or less, or 5 or less. The lower limit of the relative permittivity of the organic solvent is not particularly limited, and for example, may be greater than 0, 0.1 or greater, 0.5 or greater, or 1 or greater.

Further, the relative permittivity of the organic solvent (S) can be measured using a commercially available permittivity measuring device for a liquid (for example, “Rufuto Model 871”, manufactured by Nihon Rufuto Co., Ltd.) or the like.

The Hansen solubility parameter (dP) of the organic solvent (S) is preferably 0 to less than 16, more preferably in a range of 0 to 15, and still more preferably in a range of 0 to 14.

In a case where the Hansen solubility parameter (dP) of the organic solvent (S) is in the above-described preferable ranges, the water repellency of the electroconductive article surface is likely to be enhanced.

The organic solvent (S) may be used alone or in combination of two or more kinds thereof.

The water-repelling agent for an electroconductive article surface according to the present embodiment may contain no organic solvent having a relative permittivity of greater than 35 and may be free of one or more of the above-described organic solvents.

### <<Water>>

In order to further improve the water repellency to improve the contact angle, the water-repelling agent for an electroconductive article surface according to the present embodiment may contain water. The water may contain a trace amount of components that are inevitably mixed. As the water, water that has been subjected to a purification treatment, such as distilled water, ion exchange water, or ultrapure water, is preferable, and ultrapure water typically used for manufacture of semiconductors is more preferable.

In a case where the water-repelling agent for an electroconductive article surface contains water, the amount of water is preferably in a range of 0.01% to 25% by mass, more preferably in a range of 0.03% to 20% by mass, and still more preferably in a range of 0.05% to 15% by mass.

In a case where the amount of water is in the above-described preferable ranges, the compound (P1) is likely to be adsorbed on the electroconductive article surface.

The water-repelling agent for an electroconductive article surface according to the present embodiment may contain no water.

### <<Impurities and the Like>>

The water-repelling agent for an electroconductive article surface according to the present embodiment may contain, for example, metal impurities having metal atoms such as Fe atoms, Cr atoms, Ni atoms, Zn atoms, Ca atoms, and Pb atoms. The total amount of the metal atoms in the water-repelling agent for an electroconductive article surface according to the present embodiment is preferably 100 ppt by mass or less with respect to the total mass of the water-repelling agent for an electroconductive article surface. The lower limit of the total amount of the metal atoms is preferably as low as possible, but may be, for example, 0.001 ppt by mass or greater. The total amount of the metal atoms may be, for example, 0.001 ppt by mass to 100 ppt by mass. In a case where the total amount of the metal atoms is set to be less than or equal to the above-described preferable upper limits, the action of imparting water repellency of the water-repelling agent for an electroconductive article surface is improved. It is considered that in a case where the total amount of the metal atoms is set to greater than or equal to the above-described preferable lower limits, the metal atoms are unlikely to be present in a state of being isolated in the system and unlikely to adversely affect the production yield of the entire object to be treated.

The amount of the metal impurities can be adjusted, for example, by a purification treatment such as filtering. The purification treatment such as filtering may be performed on a part or the entirety of the raw material before the preparation of the water-repelling agent for an electroconductive article surface, or may be performed after the preparation of the water-repelling agent for an electroconductive article surface.

The water-repelling agent for an electroconductive article surface according to) the present embodiment may contain, for example, impurities derived from an organic substance (organic impurities). The total amount of the organic impurities in the water-repelling agent for an electroconductive article surface according to the present embodiment is preferably 5000 ppm by mass or less. The lower limit of the amount of the organic impurities is preferably as low as possible, and the lower limit may be, for example, 0.1 ppm by mass or greater. The total amount of the organic impurities is, for example, 0.1 ppm by mass to 5000 ppm by mass.

The water-repelling agent for an electroconductive article surface according to the present embodiment may contain, for example, an object to be counted with a size, which is counted by a light scattering in-liquid particle counter. The size of the object to be counted is, for example, 0.04 μm or greater. The number of objects to be counted in the water-repelling agent for an electroconductive article surface according to the present embodiment is, for example, 1,000 or less per 1 mL of a washing solution, and the lower limit thereof is, for example, 1 or greater. It is considered that, in a case where the number of the objects to be counted in the washing solution is in the above-described range, the action of imparting water repellency by the water-repelling agent for an electroconductive article surface is improved.

The organic impurities and/or the object to be counted may be added to the water-repelling agent for an electroconductive article surface or may be inevitably mixed into a water-repelling agent for an electroconductive article surface in a step of producing the water-repelling agent for an electroconductive article surface. Examples of a case where the organic impurities and/or the object to be counted is inevitably mixed in the step of producing the water-repelling agent for an electroconductive article surface include a case where the organic impurities are contained in the raw material (for example, the organic solvent) used for producing the water-repelling agent for an electroconductive article surface and a case where the organic impurities and/or the object to be counted are mixed from an external environment (for example, contamination) in the step of producing the water-repelling agent for an electroconductive article surface, but the present invention is not limited thereto.

In a case where the object to be counted is added to the water-repelling agent for an electroconductive article surface, the abundance ratio of the object to be counted may be adjusted for each specific size in consideration of the surface roughness of the object to be treated.

### (Storage Container)

A method for storing the water-repelling agent for an electroconductive article surface according to the present embodiment is not particularly limited, and a known storage container of the related art can also be used. The void ratio in a container during storage in the container and/or the kind of gas for filling the void portion may be appropriately set so that the stability of the water-repelling agent for an electroconductive article surface is ensured. For example, the void ratio in the storage container may be approximately in a range of 0.01% to 30% by volume.

### (Object to be Treated)

The water-repelling agent for an electroconductive article surface according to the present embodiment is used for imparting water repellency to the electroconductive article surface. The term “electroconductive article surface” denotes a surface of a region formed of an electroconductive article. The electroconductive article is not particularly limited as long as the electroconductive article is a material having electroconductivity. Examples of the electroconductive article include a material having a metal atom. Examples of the electroconductive article include a metal (for example, a single metal element), an alloy, and a metal compound (for example, a nitride). In a case where the electroconductive article is a metal, the electroconductive article surface is a metal surface. In a case where the electroconductive article is an alloy, the electroconductive article surface is an alloy surface. In a case where the electroconductive article is a metal compound, the electroconductive article surface is a surface of an electroconductive metal compound. Examples of the metal contained in the metal surface include tungsten, ruthenium, copper, aluminum, nickel, and cobalt, but the present invention is not limited thereto. Examples of the metal compound contained in the surface of the electroconductive metal compound include titanium nitride and tantalum nitride, but the present invention is not limited thereto. The metal surface preferably contains at least one metal selected from the group consisting of tungsten, ruthenium, copper, aluminum, nickel, and cobalt and more preferably ruthenium.

The electroconductive article surface may be subjected to a pretreatment with an oxidizing agent. Examples of the oxidizing agent (hereinafter, also referred to as “oxidizing agent for a pretreatment”) for performing a pretreatment on the electroconductive article surface include an oxidizing agent that removes a natural oxide film present on the electroconductive article surface and can provide a hydroxyl group to the electroconductive article surface. Examples of the oxidizing agent for a pretreatment include a peroxide such as hydrogen peroxide; perhalogen acid such as periodic acid; and oxo acid such as nitric acid or hypochlorous acid. Among these, from the viewpoint of the adsorptivity of the compound (P1), at least one selected from the group consisting of hydrogen peroxide and perhalogen acid is preferable as the oxidizing agent for a pretreatment. In a case where the surface of an inorganic substance such as SiO₂ or Al₂O₃ coexists with the electroconductive article surface, at least one selected from the group consisting of hydrogen peroxide and perhalogen acid is also preferable from the viewpoint of treating the electroconductive article surface without damaging the inorganic substance.

The oxidizing agent for a pretreatment may be used alone or in combination of two or more kinds thereof.

The electroconductive article surface may be subjected to an ozone treatment. Alternatively, the electroconductive article surface may be treated with the oxidizing agent for a pretreatment after the ozone treatment.

The electroconductive article surface which has been subjected to an ozone treatment and/or treated with the oxidizing agent for a pretreatment is modified with a hydroxyl group. The water-repelling agent for an electroconductive article surface according to the present embodiment may be used for treating the electroconductive article surface modified with a hydroxyl group.

The water-repelling agent for an electroconductive article surface according to the present embodiment may be used for treating a substrate having a surface including two or more regions formed of materials different from each other, in which at least one of the two or more regions is the electroconductive article surface.

In the substrate surface to be treated, at least one region may have an electroconductive article surface, and two or more regions may have an electroconductive article surface. In a case where two or more regions have an electroconductive article surface, these regions may have electroconductive articles that are the same as or different from each other.

The substrate surface to be treated may include a region having no electroconductive article surface (for example, a region consisting of an insulator (hereinafter, referred to as an insulator region)) in addition to the region having an electroconductive article surface. The substrate surface to be treated may include one or two or more insulator regions. In a case where the surface include two or more insulator regions, these regions may be formed of materials that are the same as or different from each other.

It is preferable that the substrate surface to be treated includes one or more regions having an electroconductive article surface and one or more insulator regions.

The insulator constituting the insulator region is formed of an insulating compound. Examples of the insulating compound include an oxide such as aluminum oxide (Al₂O₃), titanium oxide (TiO₂), zirconium oxide (ZrO₂), hafnium oxide (HfO₂), tantalum oxide (Ta₂O₅), silicon oxide (SiOx(1≤X≤2)), fluorine-containing silicon oxide (SiOF), or carbon-containing silicon oxide (SiOC); a nitride such as silicon nitride (SiN) or boron nitride (BN); a carbide such as silicon carbide (SiC); a carbonitride such as silicon carbonitride (SiCN); an oxynitride such as silicon oxynitride (SiON); an oxycarbonitride such as silicon oxycarbonitride (SiOCN); and an insulator resin such as polyimide, polyester, or a plastic resin.

The surface (the surface to be treated) of the substrate includes not only the substrate surface itself but also a surfaces of an inorganic pattern and an organic pattern provided on a substrate and a surface of an inorganic layer or an organic layer which is not patterned.

Examples of the inorganic pattern provided on a substrate include a pattern formed by preparing an etching mask using a photoresist method on a surface of an inorganic layer present on a substrate and performing an etching treatment on the surface thereof. Examples of the inorganic layer include an oxide film of an element constituting a substrate in addition to the substrate itself, and an inorganic substance film or an inorganic substance layer such as SiN, SiOx, W, Co, TiN, TaN, Ge, SiGe, Al, Al₂O₃. Ni, Ru, Cu, tetraethoxysilane (TEOS), a Low-k material, and an interlayer insulating film (ILD), formed on a substrate surface.

The inorganic substance film or the inorganic substance layer is not particularly limited, and examples thereof include an inorganic substance film or an inorganic substance layer formed in a process of preparing a semiconductor article device.

Examples of the organic pattern provided on a substrate include a resin pattern formed on a substrate using a photoresist or the like according to a photolithography method. The organic pattern can be formed, for example, by forming an organic layer, which is a photoresist film, on the substrate, exposing this organic layer through a photomask, and carrying out development thereon. Examples of the organic layer include an organic layer provided on a substrate surface itself, and an organic layer provided on a surface of a laminated film provided on a substrate surface. Such an organic layer is not particularly limited, and examples thereof include an organic substance film provided for forming an etching mask in the process of preparing a semiconductor article device.

At least one region of the substrate surface to be treated includes two or more regions including an electroconductive article surface, and proximity regions of the two or more regions may be formed of materials different from each other.

In a case where the surface to be treated includes two regions, the surface to be treated may include a first region having an electroconductive article surface and a second region (for example, an insulator region) formed of a material different from the material of the first region and adjacent to the first region. In this case, “proximity regions” may be the first region and the second region.

Each of the first region and the second region may or may not be divided into a plurality of regions.

In a case where the surface to be treated includes three or more regions, the surface to be treated may include a first region having an electroconductive article surface, a second region (for example, an insulator region) formed of a material different from the material of the first region and adjacent to the first region, and a third region formed of a material different from the material of the second region and adjacent to the second region. In such a case, “proximity regions” may be the first region and the second region (that is, adjacent regions) or the first region and the third region (that is, the regions separated by a region).

Further, in a case where the first region and the third region are formed of materials that are not different from each other (that is, both the first region and the third region have an electroconductive article surface), the “proximity regions” are the first region and the second region, or the second region and the third region (that is, adjacent regions).

Each of the first region, the second region, and the third region may or may not be divided into a plurality of regions.

The same concept can be applied even in a case where the surface to be treated includes fourth or higher regions.

The upper limit of the number of regions formed of different materials is not particularly limited as long as the effects of the present invention are not impaired, and the upper limit thereof is, for example, 7 or less, 6 or less, or typically 5 or less.

The water-repelling agent for an electroconductive article surface according to the present embodiment contains a compound (P1).

The compound (P1) is a compound in which an adsorption group selected from the group consisting of an amino group, a phosphonic acid group, an acid anhydride group, a thiol group, and an acid chloride group and a linear or branched alkyl group or a linear or branched fluorinated alkyl group are bonded to an aromatic ring. In the compound (P1), the alkyl group or the fluorinated alkyl group is hydrophobic and functions as a water-repellent group.

The compound (P1) functions as a material that is adsorbed on the electroconductive article surface by an adsorption group to form a self-assembled monolayer (SAM) (hereinafter, also referred to as “SAM agent”). Meanwhile, the compound (P1) exhibits a water repellent function due to the alkyl group or the fluorinated alkyl group.

In the compound (P1), it is considered that since these groups are bonded to the aromatic ring, excellent adsorptivity to the electroconductive article surface and excellent water repellency are exhibited without interfering with each other.

The water-repelling agent for an electroconductive article surface according to the present embodiment has high selectivity for a region having an electroconductive article surface, and thus, can be suitably applied particularly to film formation on a selected region of a substrate surface using an ALD method.

### <Second Aspect: Water Repellency-Imparting Method for Electroconductive Article Surface>

A second aspect of the present invention relates to a water repellency-imparting method for an electroconductive article surface. The method according to the present aspect includes exposing the electroconductive article surface to the water-repelling agent for an electroconductive article surface according to the first aspect.

Examples of the electroconductive article surface include those as described above. A metal surface is preferable as the electroconductive article surface.

### (Exposing Step)

A method for exposing the electroconductive article surface to the water-repelling agent for an electroconductive article surface is not particularly limited, and a known method can be used. Examples of the method for exposing the electroconductive article surface to the water-repelling agent for an electroconductive article surface include a method for immersing an object to be treated, which has an electroconductive article surface, in the water-repelling agent for an electroconductive article surface (immersion method) and a method for coating the electroconductive article surface with the water-repelling agent for an electroconductive article surface (for example, a spin coating method, a roll coating method, or a doctor blade method).

The exposure temperature may be, for example, 10° C. or higher and 90° C. or lower, and is preferably 20° C. or higher and 80° C. or lower, more preferably 20° C. or higher and 70° C. or lower, and still more preferably 20° C. or higher and 65° C. or lower.

The exposure time may be set to be sufficient for the compound (P1) to be adsorbed on the electroconductive article surface, and may be 30 seconds or longer, 1 minute or longer, 3 minutes or longer, 5 minutes or longer, 10 minutes or longer, 15 minutes or longer, 20 minutes or longer, or 25 minutes or longer. The upper limit of the exposure time is not particularly limited, but is, for example, preferably 2 hours or shorter, more preferably 90 minutes or shorter, still more preferably 60 minutes or shorter, and particularly preferably 45 minutes or shorter.

After the exposure, the substrate may be washed (for example, washed with water or an activator rinse) and/or dried (dried by nitrogen blow or the like) as necessary.

A washing method is not particularly limited, and the substrate can be washed using an appropriate washing solution according to the purpose of the electroconductive article surface. For example, in a case where the electroconductive article surface is a part of a substrate surface having an inorganic pattern or an organic pattern, a washing solution that has been used in the related art for a washing treatment of an inorganic pattern or an organic pattern can be employed as it is. Examples of the washing solution for an inorganic pattern include sulfuric acid/hydrogen peroxide water (SPM) and ammonia/hydrogen peroxide water (APM), and examples of the washing solution for an organic pattern include water and an activator rinse. The substrate may be washed with alcohol such as isopropanol and/or water.

Further, the treated substrate after being dried may be additionally subjected to a heat treatment at 100° C. or higher and 300° C. or lower as necessary.

The compound (P1) is adsorbed on the electroconductive article surface by exposing the electroconductive article surface to the water-repelling agent for an electroconductive article surface according to the first aspect. In this manner, water repellency is imparted to the electroconductive article surface.

### (Other Steps)

The method of the present embodiment may include other steps in addition to the above-described exposing step. Examples of the other steps include a pretreatment step.

A treatment that can apply a hydroxyl group to the electroconductive article surface is preferable as the pretreatment of the electroconductive article surface. Examples of the pretreatment method include an ozone treatment and a treatment using an oxidizing agent for a pretreatment. Examples of the oxidizing agent for a pretreatment include those as described above. Among these, from the viewpoint of improving water repellency of the electroconductive article surface, at least one selected from the group consisting of hydrogen peroxide and perhalogen acid is preferable as the oxidizing agent for a pretreatment.

The treatment temperature of the pretreatment is not particularly limited, but is typically in a range of 10° C. to 35° C., preferably in a range of 15° C. to 30° C., and more preferably in a range of 20° C. to 25° C.

In a case where the treatment temperature of the pretreatment is in the above-described preferable ranges, the natural oxide film on the electroconductive article surface is easily removed, and a hydroxyl group is easily applied to the electroconductive article surface.

The treatment time of the pretreatment is not particularly limited, but is typically in a range of 10 seconds to 10 minutes, preferably in a range of 20 seconds to 5 minutes, and more preferably in a range of 30 seconds to 3 minutes.

In a case where the treatment temperature of the pretreatment is in the above-described preferable ranges, the natural oxide film on the electroconductive article surface is easily removed, and a hydroxyl group is easily applied to the electroconductive article surface.

Whether water repellency has been imparted to the electroconductive article surface can be confirmed by measuring the contact angle of water with respect to the electroconductive article surface. The contact angle of water with respect to the electroconductive article surface, to which water repellency has been imparted by the method of the present embodiment, is greater than the contact angle of water with respect to the electroconductive article surface before imparting water repellency. The contact angle of water with respect to the electroconductive article surface, to which water repellency has been imparted by the method of the present embodiment, is, for example, 60° or greater, 80° or greater, 85° or greater, 90° or greater. 95° or greater, or 100° or greater. The upper limit of the contact angle is not particularly limited, but is, for example, 140° or less and typically 130° or less.

In the water repellency-imparting method for an electroconductive article surface according to the present embodiment, since the water-repelling agent for an electroconductive article surface according to the first aspect is used, water repellency can be satisfactorily imparted to the electroconductive article surface.

### <Third Aspect: Method for Selectively Imparting Water Repellency to Region Having Electroconductive Article Surface>

A third aspect of the present invention relates to a method for selectively imparting water repellency to a region having an electroconductive article surface in a substrate having a surface including two or more regions formed of materials different from each other, in which at least one of the two or more regions is the electroconductive article surface. The method according to the present aspect includes exposing the substrate surface to the water-repelling agent for an electroconductive article surface according to the first aspect.

### (Substrate)

The substrate to which water repellency is selectively imparted according to the method of the present embodiment has a surface including two or more regions formed of materials different from each other. At least one of the two or more regions in the substrate has an electroconductive article surface. A metal surface is preferable as the electroconductive article surface. Examples of the substrate include those as described above.

The substrate surface to be treated may include two or more regions, at least one of the two or more regions may have an electroconductive article surface, and proximity regions of the two or more regions may be formed of materials different from each other. In the method according to the present embodiment, the compound (P1) is selectively adsorbed in the region having an electroconductive article surface by exposing the substrate surface to be treated to the water-repelling agent for an electroconductive article surface according to the first aspect. In this manner, the contact angles of water with respect to the surfaces of the regions can be made different from each other in the two or more regions.

Among the above-described two or more regions, examples of a region where the contact angle of water tends to be greater (preferably, the surface free energy decreases) than that of other regions include regions containing at least one selected from the group consisting of tungsten (W), cobalt (Co), aluminum (Al), titanium nitride (TiN), tantalum nitride (TaN), nickel (Ni), ruthenium (Ru), and copper (Cu). Among these, a region containing at least one selected from the group consisting of tungsten, ruthenium, copper, and cobalt is preferable, and a region containing at least one selected from the group consisting of tungsten and ruthenium is more preferable. The region having an electroconductive article surface may be a region formed of an electroconductive article containing these.

Among the two or more regions, examples of a region where the contact angle of water tends to be less (preferably, the surface free energy increases) than that of other regions include regions containing at least one selected from the group consisting of silicon (Si), silicon nitride (SiN), a silicon oxide film (SiOx), germanium (Ge), silicon germanium (SiGe), tetraethoxysilane (TEOS), a Low-k material, and an interlayer insulating film (ILD). The insulator region may be a region formed of a material containing these in addition to the insulating compound.

In the method according to the present embodiment, the substrate surface to be treated may include a first region having an electroconductive article surface and a second region formed of a material different from that of the first region and adjacent to the first region. In this case, “proximity regions” may be the first region and the second region.

Each of the first region and the second region may or may not be divided into a plurality of regions.

Examples of the first region and the second region include an aspect in which a substrate surface itself is the first region and a surface of an inorganic layer formed on the substrate surface is the second region and an aspect in which a surface of a first inorganic layer formed on a substrate surface is the first region and a surface of a second inorganic layer formed on the substrate surface is the second region. An aspect in which an organic layer is formed in place of the formation of these inorganic layers can also be an exemplary example.

As the aspect in which the substrate surface itself is the first region and the surface of the inorganic layer formed on the substrate surface is the second region, from the viewpoint of region-selectively improving the hydrophobicity between two or more adjacent regions formed of materials different from each other on the substrate surface and increasing a difference in the contact angle of water between the regions, an aspect in which a surface of at least one substrate selected from the group consisting of a Si substrate, a SiN substrate, a SiOx substrate, a Ge substrate, a SiGe substrate, a TEOS film-containing substrate, a Low-k film-containing substrate, and an ILD-containing substrate is the first region and a surface of an inorganic layer formed on the substrate and containing at least one selected from the group consisting of TIN, TaN, W, Co, Al, Ni, Ru, and Cu is the second region is preferable.

As the aspect in which the surface of the first inorganic layer formed on the substrate surface is the first region and the surface of the second inorganic layer formed on the substrate surface is the second region, from the viewpoint of region-selectively improving the hydrophobicity between two or more adjacent regions formed of materials different from each other on the substrate surface and increasing a difference in the contact angle of water between the regions, an aspect in which the surface of a first inorganic layer formed on a surface of an optional substrate (for example, a Si substrate) and containing at least one selected from the group consisting of SiN, SiOx, Ge, SiGe, TEOS, a Low-k material, and ILD is the first region and a surface of a second inorganic layer formed on the substrate surface and containing at least one selected from the group consisting of TiN, TaN, W, Co, Al, Ni, Ru, and Cu is the second region is preferable.

<<Aspect in which Substrate Surface Includes 3 or More Regions>>

In a case where the substrate surface includes three or more regions, the substrate surface may include a first region having an electroconductive article surface, a second region formed of a material different from the material of the first region and adjacent to the first region, and a third region formed of a material different from the material of the second region and adjacent to the second region. In such a case, “proximity regions” may be the first region and the second region (that is, adjacent regions) or the first region and the third region (that is, the regions separated by a region).

Further, in a case where the first region and the third region are formed of materials that are not different from each other (that is, both the first region and the third region have an electroconductive article surface), the “proximity regions” are the first region and the second region, or the second region and the third region (that is, adjacent regions).

Each of the first region, the second region, and the third region may or may not be divided into a plurality of regions.

Examples of the first region, the second region, and the third region include an aspect in which the substrate surface itself is the first region, a surface of a first inorganic layer formed on the substrate surface is the second region, and a surface of a second inorganic layer formed on the substrate surface is the third region. An aspect in which an organic layer is formed in place of the formation of these inorganic layers can also be an exemplary example. An aspect in which both an inorganic layer and an organic layer are provided as regions by changing only any one of a second inorganic layer and a third inorganic layer to an organic layer may also be an exemplary example.

From the viewpoint of region-selectively improving the hydrophobicity between two or more adjacent regions formed of materials different from each other on the substrate surface and increasing a difference in the contact angle of water between the regions, an aspect in which a surface of an optional substrate (for example, a Si substrate) itself is a first region, a surface of a first inorganic layer formed on the substrate surface and containing at least one selected from the group consisting of SiN, SiOx, Ge, SiGe, TEOS, a Low-k material, and ILD is a second region, and a surface of a second inorganic layer formed on the substrate surface and containing at least one selected from the group consisting of TiN, TaN, W, Co, Al, Ni, Ru, and Cu is a third region is preferable.

The same concept can be applied to a case where the substrate surface includes a fourth or higher region.

The upper limit of the number of regions formed of different materials is not particularly limited as long as the effects of the present invention are not impaired, and the upper limit thereof is, for example, 7 or less, 6 or less, or typically 5 or less.

### (Exposing Step)

A method for exposing the substrate surface to the water-repelling agent for an electroconductive article surface according to the first aspect is not particularly limited, and a known method can be used. Examples of the method for exposing the substrate surface to the water-repelling agent for an electroconductive article surface according to the first aspect include the same methods as those described in the section of the method according to the second aspect.

### (Other Steps)

The method of the present embodiment may include other steps in addition to the above-described exposing step. Examples of the other steps include a pretreatment step. A treatment that can apply a hydroxyl group to the substrate surface is preferable as the pretreatment step. Examples of the method for the pretreatment include the same methods as those described in the section of the method according to the second aspect.

In the method of the present embodiment, the hydrophobicity of the region having an electroconductive article surface between the two or more regions can be region-selectively improved by exposing the substrate surface having two or more regions formed of materials different from each other to the water-repelling agent for an electroconductive article surface according to the first aspect.

In the substrate on which the method of the present embodiment has been performed, the contact angle of water with respect to the surface of the region having an electroconductive article surface is, for example, 60° or greater, 80° or greater, 85° or greater. 90° or greater, 95° or greater, or 100° or greater. The upper limit of the contact angle is not particularly limited, but is, for example, 140° or less and typically 130° or less.

In the substrate on which the method of the present embodiment has been performed, the contact angle of water with respect to the surface of the insulator region is not improved as much as the region having an electroconductive article surface. Therefore, in general, the difference in the contact angle of water between the region having an electroconductive article surface and the insulator region is greater after the method of the present embodiment is performed than before the method is performed. The difference in the contact angle of water between the region having an electroconductive article surface and the insulator region in the substrate on which the method of the present embodiment has been performed may be 10° or greater, and is preferably 20° or greater, more preferably 30° or greater, and still more preferably 40° or greater. The upper limit of the difference in contact angle is not particularly limited as long as the effects of the present invention are not impaired, and is, for example, 80° or less or 70° or less and typically 60° or less.

### <Fourth Aspect: Surface Treatment Method>

A fourth aspect of the present invention relates to a surface treatment method for a substrate having a surface including two or more regions formed of materials different from each other, in which at least one of the two or more regions is the electroconductive article surface. The method according to the present aspect includes exposing the substrate surface to the water-repelling agent for an electroconductive article surface according to the first aspect.

### (Substrate)

Examples of the substrate to be subjected to the surface treatment by the method of the present embodiment include the same substrates as those described in the third aspect. A metal surface is preferable as the electroconductive article surface.

### (Exposing Step)

Examples of the method for exposing the substrate surface to the water-repelling agent for an electroconductive article surface according to the first aspect include the same methods as those described in the section of the method according to the second aspect.

### (Other Steps)

The method of the present embodiment may include other steps in addition to the above-described exposing step. Examples of the other steps include a pretreatment step. A treatment that can apply a hydroxyl group to the substrate surface is preferable as the pretreatment step. Examples of the method for the pretreatment include the same methods as those described in the section of the method according to the second aspect.

### <Fifth Aspect: Method for Forming Film on Selected Region of Substrate Surface>

A fifth aspect of the present invention relates to a method for forming a film on a selected region of a substrate surface. The method of the present aspect includes performing a treatment on the substrate surface by the surface treatment method according to the fourth aspect and forming a film on the substrate surface subjected to the surface treatment by an atomic layer deposition method. In the method of the present aspect, the accumulation amount of a film-forming material from the atomic layer deposition method region-selectively varies.

### (Surface Treatment Step)

In the method of the present embodiment, first, the substrate surface is treated by the surface treatment method of the fourth aspect. Examples of the substrate to be treated include the same substrates as those described in the third aspect.

The water repellency of the region having an electroconductive article surface among the two or more regions can be selectively improved by performing the surface treatment on the substrate.

### (Film Forming Step by ALD Method)

Next, a film is formed by an ALD method on the substrate surface, which has been subjected to the surface treatment.

The water repellency of the region having an electroconductive article surface among the two or more regions is selectively improved on the substrate surface after the surface treatment. As a result, the accumulation amount of the material for forming a film can be made to be different region-selectively on the substrate surface between the two or more regions. The selective improvement of the water repellency can be confirmed by measuring the contact angle of water with respect to the surface of the region.

Specifically, in the region having an electroconductive article surface among the two or more regions, the adsorption (preferably, chemical adsorption) of the film-forming material by the ALD method is difficult. As a result, a difference in the accumulation amount of the film-forming material occurs between the two or more regions. That is, the accumulation amount of the film-forming material by the ALD method region-selectively varies. Specifically, the accumulation amount of the film-forming material in the region having an electroconductive article surface is less than the accumulation amount of the film-forming material in the insulator region.

Examples of the chemical adsorption of the film-forming material include chemical adsorption of a hydroxyl group applied to the substrate surface by performing a pretreatment.

Between the two or more regions, as a region where the contact angle of water tends to be greater (preferably, the surface free energy decreases) than that of other regions, a region containing at least one selected from the group consisting of W, Co, Al, Ni, Ru, and Cu is an exemplary example. The region having an electroconductive article surface may be a region containing these.

Between the two or more regions, as a region where the contact angle of water tends to be less (preferably, the surface free energy increases) than that of other regions, a region containing at least one selected from the group consisting of Si, Al₂O₃, SiN, SiOx, Ge, SiGe, TEOS, a Low-k material, and ILD is an exemplary example. The insulator region may be a region formed of a material containing these in addition to the insulating compound.

### <<Film Formation by ALD Method>>

A method for forming a film using an ALD method is not particularly limited, and a method for forming a thin film by adsorption (preferably chemical adsorption) using at least two gas phase reactants (hereinafter, simply referred to as “precursor gas”) is preferable.

Specifically, a method including the following steps (a) and (b) and repeating the following steps (a) and (b) at least once (one cycle) until a desired film thickness is obtained is an exemplary example.
(a) A step of exposing a substrate subjected to a surface treatment to a pulse of a first precursor gas; and
(b) A step of exposing the substrate to a pulse of a second precursor gas after the step (a)

The method may or may not include a plasma treatment step and a step of removing or discharging (purging) the first precursor gas and a reactant thereof with a carrier gas, a second precursor gas, or the like after the step (a) and before the step (b).

The method may or may not include a plasma treatment step and a step of removing or purging the second precursor gas and a reactant thereof with a carrier gas or the like after the step (b).

Examples of the carrier gas include an inert gas such as nitrogen gas, argon gas, or helium gas.

It is preferable that each pulse for each cycle and each layer to be formed are self-controlled and more preferable that each layer to be formed is a monoatomic layer.

The film thickness of the monoatomic layer can be set to, for example, 5 nm or less, preferably 3 nm or less, more preferably 1 nm or less, and still more preferably 0.5 am or less.

Examples of the first precursor gas include an organic metal, a metal halide, and a metal oxide halide, and specific examples thereof include tantalum pentaethoxide, tetrakis(dimethylamino) titanium, pentakis (dimethylamino) tantalum, tetrakis(dimethylamino) zirconium, tetrakis(dimethylamino) hafnium, tetrakis(dimethylamino) silane, copper hexafluoroacetylacetonate vinyltrimethylsilane, Zn(C₂H₅), Zn(CH₃)₂, trimethylaluminum (TMA), TaCl₅, WF₆, WOCl₄, CuCl, ZrCl₄, AlCl₃, Al(CH₃)₃, TiCl₄, SiCl₄, and HfCl₄.

Examples of the second precursor gas include a precursor gas capable of decomposing the first precursor and a precursor gas capable of removing the ligand of the first precursor, and specific examples thereof include H₂O, H₂O₂, O₂, O₃, NH₃, H₂S, H₂Se, PH₃, AsH₃, C₂H₄, and Si₂H₆.

The exposure temperature in the step (a) is not particularly limited, but is, for example, 100° C. or higher and 800° C. or lower, preferably 150° C. or higher and 650° C. or lower, more preferably 180° C. or higher and 500° C. or lower, and still more preferably 200° C. or higher and 375° C. or lower.

The exposure temperature in the step (b) is not particularly limited and may be a temperature substantially equal to or higher than the exposure temperature in the step (a).

The film to be formed by the ALD method is not particularly limited, and examples thereof include a film containing a pure element (such as Si, Cu, Ta, or W), a film containing an oxide (such as SiO₂, GeO₂, HfO₂, ZrO₂, Ta₂O₅, TiO₂, Al₂O₃, ZnO, SnO₂, Sb₂O₅, B₂O₃, In₂O₃, or WO₃), a film containing a nitride (such as Si₃N₄, TIN, AlN, BN, GaN, or NbN), a film containing a carbide (such as SiC), a film containing a sulfide (such as CdS, ZnS, MnS, WS₂, or PbS), a film containing a selenide (such as CdSe or ZnSe), a film containing a phosphide (GaP or InP), a film containing an arsenide (such as GaAs or InAs), and a mixture thereof.

In the method of the present embodiment, a film is formed by an ALD method on the substrate subjected to the surface treatment with the water-repelling agent for an electroconductive article surface according to the first aspect. In the substrate subjected to the surface treatment, the water repellency of the region having an electroconductive article surface is selectively improved. Therefore, in the region having an electroconductive article surface, the accumulation of the film-forming material by the ALD method is inhibited. As a result, in the region having an electroconductive article surface, the accumulation amount of the film-forming material by an ALD method is less than that of the insulator region. In this manner, a film can be region-selectively formed by an ALD method on the insulator region.

The water-repelling agent for an electroconductive article surface according to the first aspect has high selectivity for the electroconductive article surface. Therefore, the selectivity of film formation on the insulator region can be improved in the film formation by the ALD method by performing the surface treatment on the substrate with the water-repelling agent for an electroconductive article surface according to the first aspect.

### EXAMPLES

Hereinafter, the present invention will be described in more detail based on examples, but the present invention is not limited to these examples.

### Preparation of Water-Repelling Agent for Electroconductive Article Surface

### Examples 1 and 2 and Comparative Examples 1 to 3

A water-repelling agent for an electroconductive article surface of each example listed in Table 1 was prepared. The concentration of the compound in the water-repelling agent for an electroconductive article surface was adjusted to 0.1% by mass with respect to the total mass of the water-repelling agent for an electroconductive article surface. The relative permittivity of toluene used as an organic solvent was 2.37.

TABLE 1

| | Compound | Organic solvent |
|---|---|---|
| Example 1 | 4-n-Octadecylaniline | Toluene |
| Example 2 | 4-Methylbenzenethiol | Toluene |
| Comparative Example 1 | Octadecylphosphonic acid | Toluene |
| Comparative Example 2 | Phenylphosphonic acid | Toluene |
| Comparative Example 3 | Benzenethiol | Toluene |

### <Water-Repellent Treatment (1)>

A water-repellent treatment was performed on a ruthenium substrate with the water-repelling agent for an electroconductive article surface of each example using the following method.

### Pretreatment

The substrate was subjected to an ozone (O₃) treatment for 15 minutes. Next, the substrate was subjected to a pretreatment by being immersed in a H₂O₂ aqueous solution having a concentration of 3.59% by mass at room temperature for 1 minute. After the pretreatment, the substrate was washed with ion exchange distilled water for 1 minute. The substrate after being washed with water was dried by nitrogen stream.

### Water-Repellent Treatment

The substrate was subjected to a surface treatment by immersing the dried substrate in the water-repelling agent for an electroconductive article surface of each example at room temperature for 30 minutes. The substrate that had been subjected to the water-repellent treatment was washed with isopropanol for 1 minute and further washed with ion exchange distilled water for 1 minute. The washed substrate was dried by a nitrogen stream to obtain a substrate that had been subjected to the water-repellent treatment.

<Measurement (1) of Contact Angle with Water>

The contact angle of water was measured for each of the substrates after the water-repellent treatment.

The contact angle of water was measured by dropping pure water droplets (2.0 μL) on the surface of the surface-treated substrate using Dropmaster700 (manufactured by Kyowa Interface Science Co., Ltd.), and the contact angle obtained 2 seconds after the dropping of the droplets was used for the measurement. The results are listed in Table 2.

TABLE 2

| | | Contact angle |
|---|---|---|
| | Compound | (° C.) |
| Example 1 | 4-n-Octadecylaniline | 118.4 |
| Example 2 | 4-Methylbenzenethiol | 65.6 |
| Comparative Example 1 | Octadecylphosphonic acid | 61.7 |
| Comparative Example 2 | Phenylphosphonic acid | 58.3 |
| Comparative Example 3 | Benzenethiol | 54.4 |
| Without water-repellent | — | 14.4 |
| treatment | | |

As shown in the results listed in Table 2, it was shown that the water-repelling agents for an electroconductive article surface of Examples 1 and 2 had the water repellent effect higher than that of the water-repelling agents for an electroconductive article surface of Comparative Examples 1 to 3.

### <ALD Treatment (1)>

The water-repellent treatment was performed on a ruthenium substrate using the water-repelling agent for an electroconductive article surface of each example according to the description in <Water-repellent treatment (1)>. Next, an Al₂O₃ film was formed on the ruthenium substrate by performing an ALD cycle treatment 18 times under the following conditions.
Atomic layer deposition (ALD) device: AT-410 (manufactured by Anric Technologies LLC)
Chamber temperature: 150° C.
Precursor: trimethylaluminum and H₂O
   <Measurement (1) of Al₂O₃ Film Formation Inhibition Rate>

In the ruthenium substrate after film formation of the Al₂O₃ film, the Al₂O₃ film was measured with a fluorescence X-ray analysis (XRF) device (ZSX Primus, manufactured by Rigaku Corporation). The Al₂O₃ film formation inhibition rate was calculated by Equation (1). The results are listed in Table 3.

Al₂O₃ film formation inhibition rate (%)=(T0−Tn)/T0×100 (1)
Tn: film thickness of Al₂O₃ film in case where ALD treatment was performed after water-repellent treatment
T0: film thickness of Al₂O₃ film in case where ALD treatment was performed without performing water-repellent treatment

TABLE 3

| | | Inhibition |
|---|---|---|
| | | rate in Ru |
| | Compound | substrate (%) |
| Example 1 | 4-n-Octadecylaniline | 52.7 |
| Comparative Example 1 | Octadecylphosphonic acid | 33.9 |
| Comparative Example 2 | Phenylphosphonic acid | 11.2 |
| Comparative Example 3 | Benzenethiol | 10.9 |

As shown in the results listed in Table 3, it was found that the ruthenium surface treated with the water-repelling agent for an electroconductive article surface of Example 1 had an Al₂O₃ film formation inhibition rate higher than that of the ruthenium surface treated with the water-repelling agent for an electroconductive article surface of the comparative example.

### <Water-Repellent Treatment (2)>

The SiO₂ substrate was subjected to a water-repellent treatment with the water-repelling agent for an electroconductive article surface of each example using the following method.

### Pretreatment

The substrate was subjected to an ozone (O₃) treatment for 15 minutes. Next, the substrate was subjected to a pretreatment by being immersed in a H₂O₂ aqueous solution having a concentration of 3.59% by mass at room temperature for 1 minute. After the pretreatment, the substrate was washed with ion exchange distilled water for 1 minute. The substrate after being washed with water was dried by nitrogen stream.

### Water-Repellent Treatment

The substrate was subjected to a surface treatment by immersing the dried substrate in the water-repelling agent for an electroconductive article surface of each example at room temperature for 30 minutes. The substrate that had been subjected to the water-repellent treatment was washed with isopropanol for 1 minute and further washed with ion exchange distilled water for 1 minute. The washed substrate was dried by a nitrogen stream to obtain a substrate that had been subjected to the water-repellent treatment.

### <ALD Treatment (2)>

An Al₂O₃ film was formed on the SiO₂ substrate subjected to the water-repellent treatment under the same conditions as in the ALD treatment (1) except for the substrate.

<Measurement (2) of Al₂O₃ Film Formation Inhibition Rate>

In the SiO₂ substrate after film formation of the Al₂O₃ film, the Al₂O₃ film was measured with a fluorescence X-ray analysis (XRF) device (ZSX Primus, manufactured by Rigaku Corporation). The Al₂O₃ film formation inhibition rate was calculated by Equation (1). The results are listed in Table 4.

TABLE 4

| | | Inhibition |
|---|---|---|
| | | rate in SiO₂ |
| | Compound | substrate (%) |
| Example 1 | 4-n-Octadecylaniline | 1.8 |
| Comparative Example 1 | Octadecylphosphonic acid | 6.9 |
| Comparative Example 2 | Phenylphosphonic acid | 7.5 |
| Comparative Example 3 | Benzenethiol | 0.0 |

As shown in the results listed in Table 4, it was found that the SiO₂ surface treated with the water-repelling agent for an electroconductive article surface of Example 1 had an Al₂O₃ film formation inhibition rate lower than those of the SiO₂ surfaces treated with the water-repelling agents for an electroconductive article surface of Comparative Examples 1 and 2.

As shown in the results listed in Tables 3 and 4, it was found that the film formation of the Al₂O₃ film was selectively inhibited on the ruthenium surface by performing the water-repellent treatment with the water-repelling agent for an electroconductive article surface of Example 1.

### Preparation of Water-Repelling Agent for Electroconductive Article Surface

### Examples 3 to 8

A water-repelling agent for an electroconductive article surface of each example listed in Table 5 was prepared. The concentration of the compound in the water-repelling agent for an electroconductive article surface was adjusted to 0.1% by mass with respect to the total mass of the water-repelling agent for an electroconductive article surface.

TABLE 5

| | | | Relative |
|---|---|---|---|
| | | | permittivity of |
| | Compound | Organic solvent | organic solvent |
| Example 3 | 4-n-Octadecylaniline | Cyclohexane | 1.99 |
| Example 4 | 4-n-Octadecylaniline | Decane | 1.99 |
| Example 5 | 4-n-Octadecylaniline | Decahydronaph- | 2.16 |
| | | thalene | |
| Example 6 | 4-n-Octadecylaniline | Butyl acetate | 4.55 |
| Example 7 | 4-n-Octadecylaniline | 4-Methyl-2-pentanol | 10.47 |
| Example 8 | 4-n-Octadecylaniline | 1-Nonanol | 9.13 |

### <Measurement of Contact Angle of Water>

The water-repellent treatment was performed on a ruthenium substrate according to the description in <Water-repellent treatment (1)>. Thereafter, the contact angle of water was measured according to the description of <Measurement (1) of contact angle of water>. The results are listed in Table 6.

<Measurement of Al₂O₃ Film Formation Inhibition Rate>

The water-repellent treatment was performed on a ruthenium substrate according to the description in <Water-repellent treatment (1)>. Thereafter, an Al₂O₃ film was formed on the ruthenium substrate according to the description in <ALD treatment (1)>. The film thickness of the Al₂O₃ film was measured and the Al₂O₃ film formation inhibition rate was calculated according to the description in <Measurement (1) of Al₂O₃ film formation inhibition rate>. The results are listed in Table 6.

TABLE 6

| | Contact angle | Inhibition rate in Ru substrate |
|---|---|---|
| | (° C.) | (%) |
| Example 3 | 117.4 | 55 |
| Example 4 | 114.6 | 54 |
| Example 5 | 118.2 | 53 |
| Example 6 | 100.6 | 34 |
| Example 7 | 100.5 | 28 |
| Example 8 | 95.0 | 20 |

The ruthenium surfaces treated with the water-repelling agents for an electroconductive article surface of Examples 3 to 8 all exhibited satisfactory water repellency. As shown in the results of the contact angles and the inhibition rates, it was suggested that a solvent having a low dielectric constant was preferable.

Hereinbefore, the preferable examples of the present invention have been described, but the present invention is not limited thereto. Additions, omissions, substitutions, and other modifications can be made without departing from the scope of the invention. Accordingly, the present invention is not to be considered as being limited by the foregoing description and is only limited by the scope of the appended claims.

1. A water-repelling agent for an electroconductive article surface, comprising:
a compound (P1) that contains an aromatic ring, an adsorption group which is bonded to the aromatic ring and selected from the group consisting of an amino group, a phosphonic acid group, an acid anhydride group, a thiol group, and an acid chloride group, and a linear or branched alkyl group or a linear or branched fluorinated alkyl group bonded to the aromatic ring.

2. The water-repelling agent for an electroconductive article surface according to claim 1,
wherein the compound (P1) is a compound represented by General Formula (P1-1), 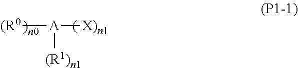
wherein R⁰ represents a linear or branched alkyl group or a linear or branched fluorinated alkyl group, R¹ represents an organic group, provided that a group corresponding to R⁰ is excluded, A represents a group in which (n0+n1+nx) hydrogen atoms are removed from a benzene ring, a group in which (n0+n1+nx) hydrogen atoms are removed from a naphthalene ring, or a group in which (n0+n1+nx) hydrogen atoms are removed from a biphenyl ring, X represents an adsorption group selected from the group consisting of an amino group, a phosphonic acid group, an acid anhydride group, a thiol group, and an acid chloride group, no and nx each independently represent an integer of 1 or greater, and n1 represents an integer of 0 or greater, where n0+n1+nx≤6 is satisfied in a case where A represents the group in which (n0+n1+nx) hydrogen atoms are removed from a benzene ring, n0+n1+nx≤8 is satisfied in a case where A represents the group in which (n0+n1+nx) hydrogen atoms are removed from a naphthalene ring, and n0+n1+nx≤10 is satisfied in a case where A represents the group in which (n0+n1+nx) hydrogen atoms are removed from a biphenyl ring, a plurality of R⁰'s may be the same as or different from each other in a case where no represents 2 or greater, a plurality of R¹'s may be the same as or different from each other in a case where n1 represents 2 or greater, and a plurality of X's may be the same as or different from each other in a case where nx represents 2 or greater.

3. The water-repelling agent for an electroconductive article surface according to claim 1,
wherein the compound (P1) is a compound represented by General Formula (P1-1-1), 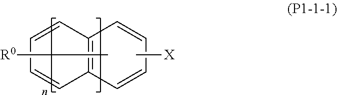
wherein R⁰ represents a linear or branched alkyl group or a linear or branched fluorinated alkyl group, X represents an adsorption group selected from the group consisting of an amino group, a phosphonic acid group, an acid anhydride group, a thiol group, and an acid chloride group, and n represents 0 or 1.

4. The water-repelling agent for an electroconductive article surface according to claim 1,
wherein the electroconductive article surface contains at least one selected from the group consisting of tungsten, ruthenium, copper, and cobalt.

5. The water-repelling agent for an electroconductive article surface according to claim 1,
wherein the water-repelling agent for an electroconductive article surface is used for treating a substrate having a surface including two or more regions formed of materials different from each other, in which at least one of the two or more regions is the electroconductive article surface.

6. A water repellency-imparting method for an electroconductive article surface, the method comprising:
exposing the electroconductive article surface to the water-repelling agent for an electroconductive article surface according to claim 1.

7. A method for selectively imparting water repellency to a region having an electroconductive article surface in a substrate having a surface including two or more regions formed of materials different from each other, in which at least one of the two or more regions is the electroconductive article surface, the method comprising:
exposing the substrate surface to the water-repelling agent for an electroconductive article surface according to claim 1.

8. A surface treatment method for a substrate having a surface including two or more regions formed of materials different from each other, in which at least one of the two or more regions is an electroconductive article surface, the method comprising:
exposing the surface to the water-repelling agent for an electroconductive article surface according to claim 1.

9. A method for forming a film on a selected region of a substrate surface, the method comprising:
performing a surface treatment on the substrate surface by the surface treatment method according to claim 8; and
forming a film on the substrate surface subjected to the surface treatment by an atomic layer deposition method,
wherein an accumulation amount of a film-forming material from the atomic layer deposition method region-selectively varies.
